(19) United States
(12) Patent Application Publication
(10) Pub. No.: US 2010/0084758 A1
(43) Pub. Date: Apr. 8, 2010

(54) Semiconductor package

(75) Inventor: Younjo Mun, Cheonan-si (KR)

Correspondence Address: HARNESS, DICKEY & PIERCE, P.L.C., P.O. BOX 8910, RESTON, VA, 20195, US

(73) Assignee: Samsung Electronics Co.,Ltd.

(21) Appl. No.: 12/585,274

(22) Filed: Sep. 10, 2009

(30) Foreign Application Priority Data
Oct. 2, 2008 (KR) 10-2008-0097201

(51) Int. Cl. H01L 23/498

(52) U.S. Cl. 257/690; 257/E23.06

(57) ABSTRACT

Provided is a semiconductor package including a mark pattern and a method of manufacturing the same. The semiconductor package may include at least one semiconductor chip including a circuit region, a protection layer covering the circuit region, a molding portion sealing the protection layer and the at least one semiconductor chip, the molding portion having an exposed top surface on the circuit region, and a mark pattern at the top surface of the molding portion. A method of fabricating the semiconductor package may include providing at least one semiconductor chip including a circuit region, forming a protection layer covering the circuit region, forming a molding portion sealing the protection layer and the at least one semiconductor chip, the molding portion having an exposed top surface on the circuit region, and forming a mark pattern at the top surface of the molding portion using a laser.

### CROSS-REFERENCE TO RELATED APPLICATIONS

This application claims priority under 35 U.S.C. § 119 to Korean Patent Application No. 10-2008-97201, filed on Oct. 2, 2008, in the Korean Intellectual Property Office (KIPO), the entire contents of which are herein incorporated by reference.

### BACKGROUND

1. Field

Example embodiments relate to a semiconductor package, and more particularly, to a semiconductor package including a mark pattern and a method of manufacturing the same.

2. Description of the Related Art

As electronic devices become relatively light, thin, short, and small, a high density and a high mounting of a package, which is a key element of an electronic device, becomes a primary factor in the design of such electronic devices. In the case of a computer, a size of a semiconductor device, such as a random access memory (RAM) or a flash memory, increases according to an increase of a memory capacity while a package size is required to be relatively small for the reasons described above.

Many methods have been suggested to reduce a package size. For example, a stack type semiconductor package in which a plurality of semiconductor chips or a semiconductor device package is stacked has been introduced. Also, there is a semiconductor module wherein a plurality of semiconductor chips, a plurality of semiconductor device packages and/or a stack type semiconductor package are two-dimensionally mounted at least one side of a printed circuit board (PCB).

These packages may be classified into a multi-chip package (MCP) that a plurality of semiconductor chips performing different functions is mounted (or stacked) and a stack type package of a semiconductor chip that a plurality of semiconductor chips is stacked to embody a high capacity.

### SUMMARY

Example embodiments relate to a semiconductor package, and more particularly, to a semiconductor package including a mark pattern and a method of manufacturing the same.

In accordance with example embodiments, a semiconductor package may include at least one semiconductor chip including a circuit region, a protection layer covering the circuit region, a molding portion sealing the protection layer and the at least one semiconductor chip, the molding portion having an exposed top surface on the circuit region, and a mark pattern at the top surface of the molding portion.

In accordance with example embodiments, a method of manufacturing a semiconductor package may include providing at least one semiconductor chip including a circuit region, forming a protection layer covering the circuit region, forming a molding portion sealing the protection layer and the at least one semiconductor chip, the molding portion having an exposed top surface on the circuit region, and forming a mark pattern at the top surface of the molding portion using a laser.

Example embodiments provide a semiconductor package. The package may include at least one semiconductor chip including a circuit region, a molding portion having an exposed top surface and sealing up the semiconductor chip, a mark pattern formed on the exposed top surface using a laser, and a protection layer which covers the circuit region and reflects or absorbs light emitted from the laser, the protection layer being disposed between the top surface and the semiconductor chip.

Example embodiments provide a method of manufacturing the semiconductor package. The method may include providing at least one semiconductor chip including a circuit region, forming a protection layer covering the circuit region, forming a molding portion sealing up the protection layer and the semiconductor chip, the molding portion having an exposed top surface on the circuit region; and forming a mark pattern at the top surface of the molding portion using a laser.

### BRIEF DESCRIPTION OF THE FIGURES

The accompanying figures are included to provide a further understanding of example embodiments, and are incorporated in and constitute a part of this specification. The drawings illustrate example embodiments and, together with the description, serve to explain principles of example embodiments. In the figures:

FIG. 1A is a cross sectional view of a semiconductor package according to example embodiments;

FIG. 1B is an enlarged view enlarging an M portion of FIG. 1A;

FIG. 1C is a top plan view of an M portion of FIG. 1A;

FIGS. 2 through 6 are cross sectional views illustrating a method of manufacturing a semiconductor package according to example embodiments;

FIG. 7 is a cross sectional view of a semiconductor package according to example embodiments;

FIG. 8 is a cross sectional view of a semiconductor package according to example embodiments;

FIG. 9 is a cross sectional view of a semiconductor package according to example embodiments;

FIG. 10 is a cross sectional view of a memory card system including a semiconductor package according to example embodiments; and

FIG. 11 is a block diagram of an electronic device including a semiconductor package according to example embodiments.

### DETAILED DESCRIPTION OF EXAMPLE EMBODIMENTS

Example embodiments now will be described more fully hereinafter with reference to the accompanying drawings, in which example embodiments are shown. Example embodiments may, however, be embodied in many different forms and should not be construed as limited to example embodiments set forth herein. Rather, example embodiments are provided so that this disclosure will be thorough and complete, and will fully convey the scope of example embodiments to those skilled in the art. In the drawings, the size and relative sizes of layers and regions may be exaggerated for clarity. Like numbers refer to like elements throughout.

It will be understood that when an element is referred to as being “connected” or “coupled” to another element, it can be directly connected or coupled to the other element or intervening elements may be present. In contrast, when an element is referred to as being “directly connected” or “directly coupled” to another element, there are no intervening elements present. As used herein, the term “and/or” includes any and all combinations of one or more of the associated listed items and may be abbreviated as “i/”.

It will be understood that, although the terms first, second, etc. may be used herein to describe various elements, these elements should not be limited by these terms. These terms are only used to distinguish one element from another. For example, a first region/layer could be termed a second region/layer, and, similarly, a second region/layer could be termed a first region/layer without departing from the teachings of the disclosure.

The terminology used herein is for the purpose of describing particular embodiments only and is not intended to be limiting of the invention. As used herein, the singular forms “a”, “an” and “the” are intended to include the plural forms as well, unless the context clearly indicates otherwise. It will be further understood that the terms “comprises” and/or “comprising,” or “includes” and/or “including” when used in this specification, specify the presence of stated features, regions, integers, steps, operations, elements, and/or components, but do not preclude the presence or addition of one or more other features, regions, integers, steps, operations, elements, components, and/or groups thereof.

Example embodiments may be described with reference to cross-sectional illustrations, which are schematic illustrations of idealized example embodiments. As such, variations from the shapes of the illustrations, as a result, for example, of manufacturing techniques and/or tolerances, are to be expected. Thus, example embodiments should not be construed as limited to the particular shapes of regions illustrated herein, but are to include deviations in shapes that result from, e.g., manufacturing. For example, a region illustrated as a rectangle may have rounded or curved features. Thus, the regions illustrated in the figures are schematic in nature and are not intended to limit the scope of the present invention.

Unless otherwise defined, all terms (including technical and scientific terms) used herein have the same meaning as commonly understood by one of ordinary skill in the art to which example embodiments belongs. It will be further understood that terms, such as those defined in commonly used dictionaries, should be interpreted as having a meaning that is consistent with their meaning in the context of the relevant art and/or the present application, and will not be interpreted in an idealized or overly formal sense unless expressly so defined herein.

In the drawings, the thickness of layers and regions are exaggerated for clarity. It will also be understood that when an element such as a layer, region or substrate is referred to as being “on” or “onto” another element, it may lie directly on the other element or intervening elements or layers may also be present. Like reference numerals refer to like elements throughout the specification.

Spatially relative terms, such as “beneath,” “below,” “above,” “upper,” “top,” “bottom” and the like, may be used to describe an element and/or feature's relationship to another element(s) and/or feature(s) as, for example, illustrated in the figures. It will be understood that the spatially relative terms are intended to encompass different orientations of the device in use and/or operation in addition to the orientation depicted in the figures. For example, when the device in the figures is turned over, elements described as below and/or beneath other elements or features would then be oriented (rotated 90 degrees or at other orientations) and the spatially relative descriptors used herein interpreted accordingly. As used herein, “height” refers to a direction that is generally orthogonal to the faces of a substrate.

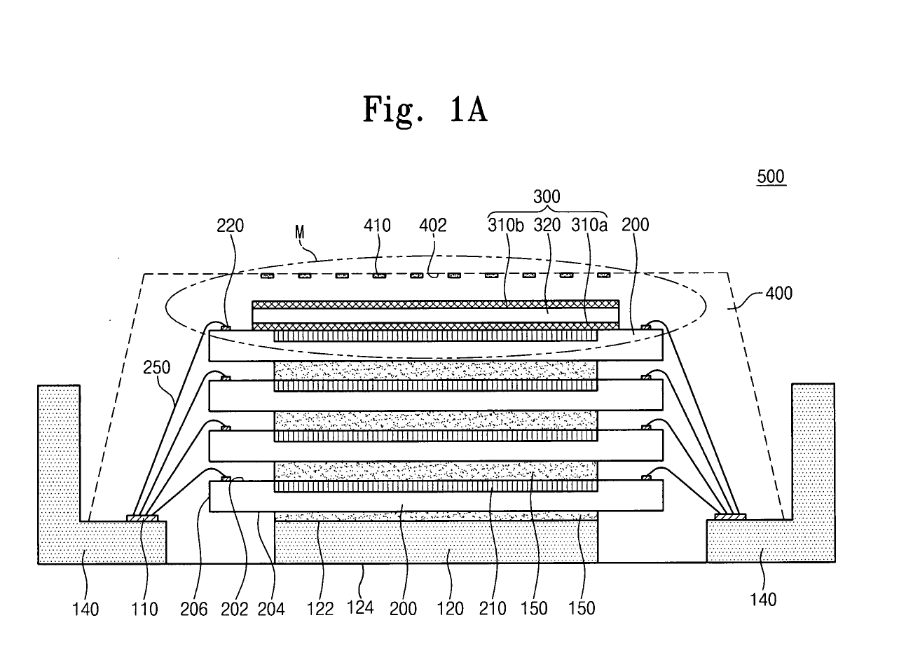

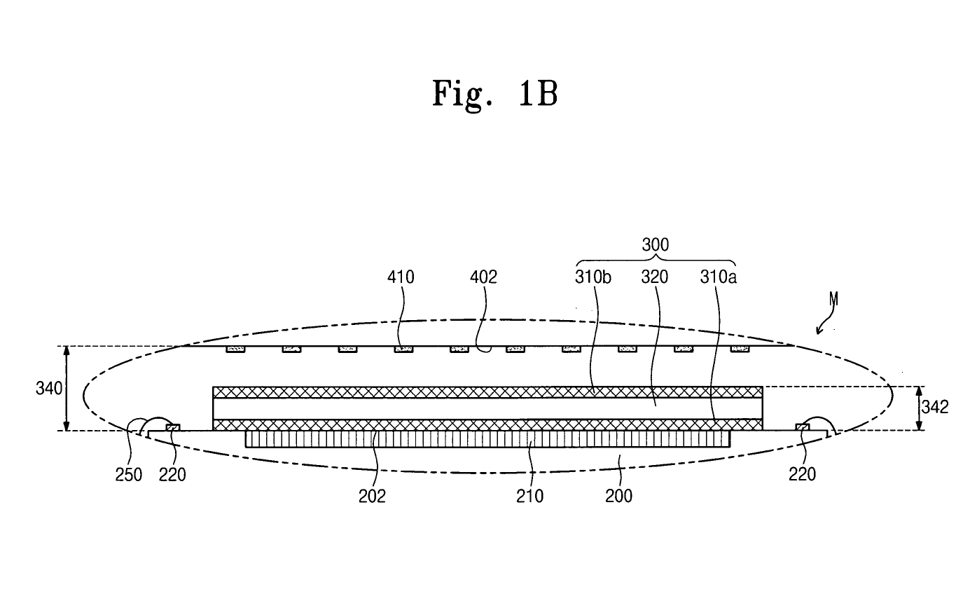

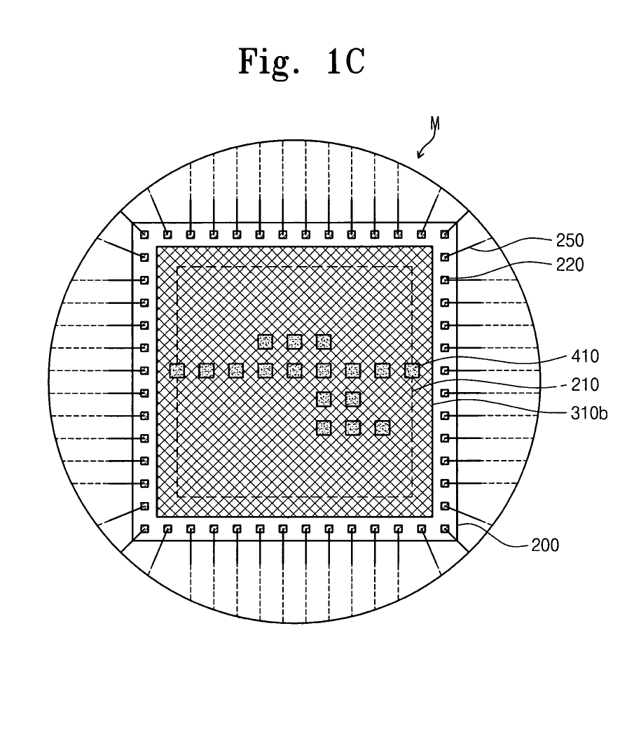

FIG. 1A is a cross sectional view of a semiconductor package according to example embodiments. FIG. 1B is an enlarged view enlarging an M portion of FIG. 1A. FIG. 1C is a top plan view of an M portion of FIG. 1A.

Referring to FIGS. 1A, 1B and 1C, a semiconductor package 500 according to example embodiments may include a die paddle 120, semiconductor chips 200 on the die paddle 120, lead patterns 140 spaced apart from the die paddle 120, a protection layer 300 on the semiconductor chips 200 and a molding portion 400. The semiconductor package 500 may, for example, be a lead exposing type package.

The die paddle 120 may have a top surface 122 and a bottom surface 124 facing each other. The bottom surface 124 of the die paddle 120 may be exposed.

The semiconductor chips 200 may be stacked on the die paddle 120. An adhesive layer 150 may be disposed between the die paddle 120 and the lowest semiconductor chip among the semiconductor chips 200, and between the semiconductor chips 200. The semiconductor chips 200 may include a nonvolatile memory, a volatile memory capable of a random access and/or a variety of other kinds of memories. The semiconductor chips 200 may, for example, include a flash memory chip, a PRAM chip, a MRAM chip, a SRAM chip, a DRAM chip or combinations thereof.

The semiconductor chip 200 may include a first surface 202 and a second surface 204 facing each other. Each of the semiconductor chips 200 may include a circuit region 210. The circuit region 210 may include a conductive circuit pattern (not shown) and an interconnection pattern (not shown). The interconnection pattern may, for example, be electrically connected to the circuit pattern and disposed on the circuit pattern. The circuit region 210 may be provided on the first surface 202 of the semiconductor chip 200. A chip pad 220 may be electrically connected to the interconnection pattern and may be disposed to be adjacent to an edge of the first surface 202 of the semiconductor chip 200. A plurality of the chip pads 220 may be disposed to be spaced apart from one another along a side surface 206 of the edge.

The lead patterns 140 may be spaced apart from the die paddle 120 so as to be electrically separated from the die paddle 120. A plurality of the lead patterns 140 corresponding to the chip pads 220 may be disposed to be spaced apart from one another. Each of the lead patterns 140 may be electrically separated from one another. The lead patterns 140 may be disposed around the die paddle 120. For example, the lead patterns 140 may be disposed to be a radial shape with respect to the die paddle 120. That is, the die paddle 120 may be positioned in a center of a radial shape. Each of the lead patterns 140 may include an exposed bottom surface and an exposed side surface as a connection terminal to electrically connect the lead patterns 140 to an external device (not shown). Each of the lead patterns 140 may include a conductive pad 110 (e.g., a plated layer). One conductive pad 110 corresponding to the chip pad 220 may be disposed on each of the lead patterns 140. The conductive pad 110 and the chip pad 220 may be electrically connected to each other through a conductive line 250. The conductive line 250 may be formed by a wire bonding technique.

The molding portion 400 may seal the semiconductor chip 200, the die paddle 120, the lead patterns 140, the conductive line 250 and the protection layer 300. A bottom surface 124 of the die paddle 120 and the bottom surface and the side surface of the lead pattern 140 may be exposed to the outside. The exposed surfaces of the lead pattern 140 may be used to electrically connect the lead pattern 140 to an external device (not shown).

A mark pattern 410 may be disposed at a top surface 402 of the molding portion 400. The mark pattern 410 may extend into the molding portion 400 to have a predetermined or preset depth. The predetermined or preset depth may, for example, be about 45 um to about 65 um. The mark pattern 410 may represent product information which may be, for example, a lot number and/or a product name.

The protection layer 300 may be disposed between the top surface 402 of the molding portion 400 and the highest semiconductor chip among the semiconductor chips 200. The protection layer 300 may cover the circuit region 210 of the highest semiconductor chip 200. The protection layer 300 may cover the circuit region 210 of the semiconductor chip adjacent to the mark pattern 410. The protection layer 300 may cover a portion of the circuit region 210 under the mark pattern 410. The chip pads 220 may be disposed to surround the vicinity of the protection layer 300. The protection layer 300 may have a multilayer structure. The protection layer 300 may include a first cutoff layer 310a, a second cutoff layer 310b and a supporting layer 320 disposed between the first and second cutoff layers 310a and 310b. The first and second cutoff layers 310a and 310b may cutoff light emitted from a laser, for example, infrared light. The first and second cutoff layers 310a and 310b may include a bisphenol resin, a novolac resin, and/or a combination thereof. The first and second cutoff layers 310a and 310b may be a layer of a film type having an adhesive property. Thus, the first cutoff layer 310a may adhere to the first surface 202 of the semiconductor chip 200. The protection layer 300 may be comprised of only the first cutoff layer 310a. The supporting layer 320 may absorb an external shock and support the first and second cutoff layers 310a and 310b. The supporting layer 320 may include a metal layer or a nonmetal layer. The supporting layer 320 may, for example, include a nickel layer or a copper layer. A nonmetal layer may, for example, be a layer of film type and include a heat hardening material. The protection layer 300 may have a thickness 342 of about 10 to about 100 um. The supporting layer 320 may absorb an external shock and support the first and second cutoff layers 310a and 310b. A drawing mark 340 of FIG. 1B is a distance between the top surface 402 of the molding portion 400 and the first surface 202 of the highest semiconductor chip 200.

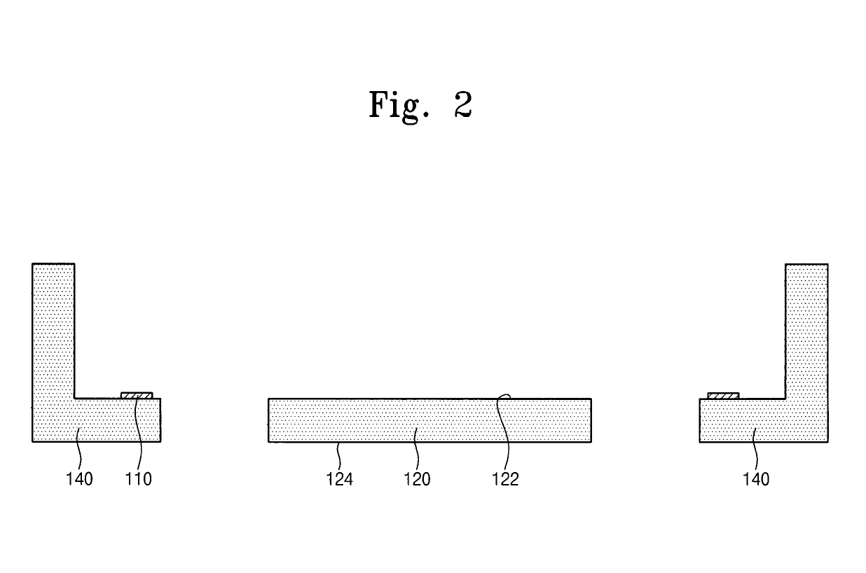

FIGS. 2 through 6 are cross sectional views illustrating a method of manufacturing a semiconductor package according to example embodiments.

Referring to FIG. 2, a lead pattern 140 separated from a die paddle 120 may be provided. The die paddle 120 may have a top surface 122 and a bottom surface 124 facing each other. The die paddle 120 may be formed of a conductive material, for example, a metal including copper and/or or compound metal having relatively good electrical and heat conductivities. The lead patterns 140 may be spaced apart from the die paddle 120 to be electrically separated from the die paddle 120. A plurality of the lead patterns 140 may be disposed to be spaced apart from one another. Each of the lead patterns 140 may be electrically separated from one another. The lead patterns 140 may be disposed around the die paddle 120. For example, the lead patterns 140 may be disposed radially with respect to the die paddle 120. That is, the die paddle 120 may be positioned in a center of a radial shape. The lead pattern 140 may, for example, include copper which may be the same material as the die paddle 120.

A conductive pad 110 may be formed on the lead pattern 140 adjacent to the die paddle 120. The conductive pad 110 may be a plated layer and one conductive pad 110 may be disposed on each of the lead patterns 140. The conductive pad 110 may include silver (Ag) or palladium (Pd). The conductive pad 110 may be disposed to improve an electrical contact with a conductive line 250 which will be described in a subsequent process.

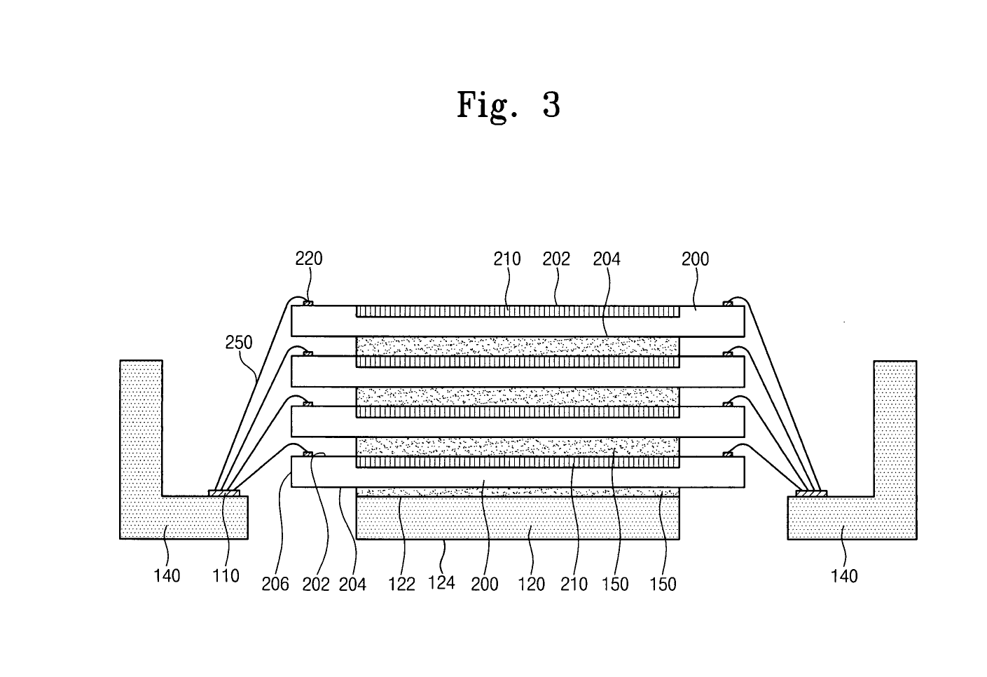

Referring to FIG. 3, semiconductor chips 200 may be sequentially stacked on the die paddle 120. An adhesive layer 150 may be disposed between the lowest semiconductor chip among the semiconductor chips 200 and the die paddle 120 and between the semiconductor chips 200. The adhesive layer 150 may be, for example, an epoxy adhesive and/or a silicon adhesive.

Each of the semiconductor chips 200 may include a first surface 202 and a second surface 204 facing each other. Each of the semiconductor chips 200 may include a circuit region 210. The circuit region 210 may include a circuit pattern (not shown) and an interconnection pattern (not shown). The interconnection pattern may, for example, be electrically connected to the circuit pattern and disposed on the circuit pattern. A chip pad 220 ma y be disposed to be adjacent to an edge of the first surface 202 of the semiconductor chip 200. The chip pad 220 may be electrically connected to the interconnection pattern. A plurality of the chip pads 220 may be disposed to be spaced apart from one another along a side surface 206 of the edge. The chip pad 220 may be formed of a conductive material, for example, a compound metal and/or a metal including aluminum and/or copper.

The conductive pad 110 and the chip pad 220 may be electrically connected to each other through a conductive line 250. The conductive line 250 may be formed via a wire bonding technique. The conductive line 250 may be formed of a conductive metal, for example, gold.

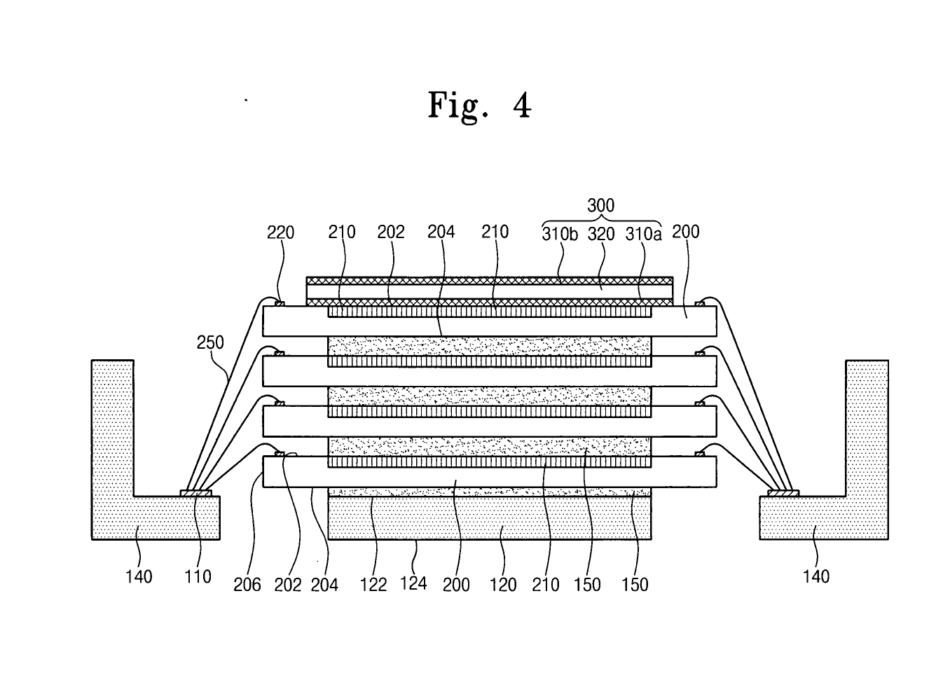

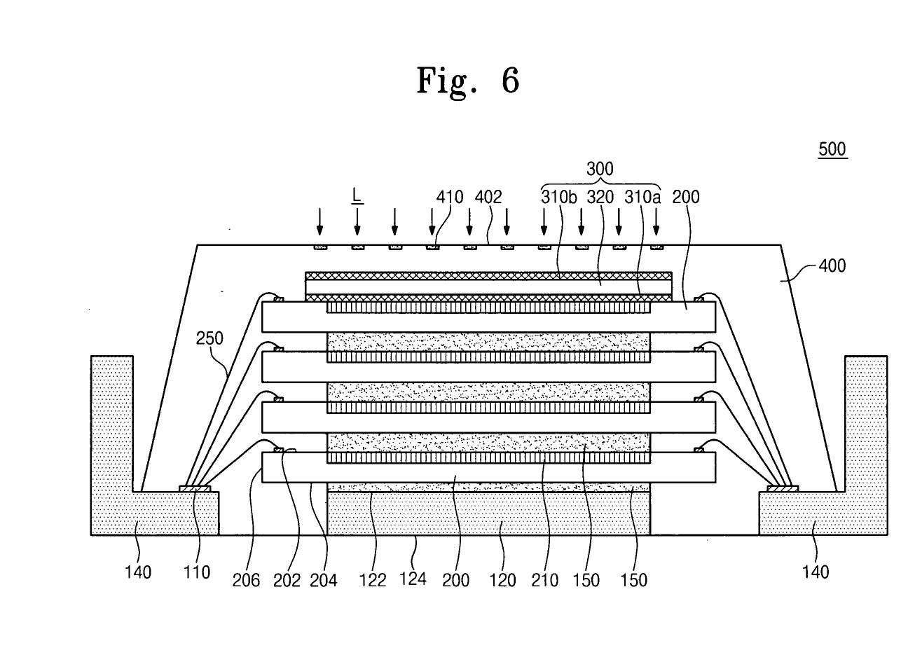

Referring to FIG. 4, a protection layer 300 may be formed on the semiconductor chips 200. The protection layer 300 may cover a circuit region 210 of the highest semiconductor chip. The protection layer 300 may cover a portion of the circuit region 210 under a mark pattern (410 of FIG. 6) which may be formed in a subsequent process. The chip pads 220 of the highest semiconductor chip may surround a vicinity of the protection layer 300. The protection layer 300 may have a multilayer structure. The protection layer 300 may include a first cutoff layer 310a, a second cutoff layer 310b and a supporting layer 320 disposed between the first and second cutoff layers 310a and 310b. The first and second cutoff layers 310a and 310b may reflect or absorb light emitted from a laser, for example, infrared light. The first and second cutoff layers 310a and 310b may include a bisphenol resin, a novolac resin, and/or combination thereof. The first and second cutoff layers 310a and 310b may be a layer of a film type having an adhesive property. Thus, the first cutoff layer 310a may adhere to the first surface 202 of the semiconductor chip 200. The protection layer 300 may be comprised of only the first cutoff layer 310a. The supporting layer 320 may absorb an external shock and support the first and second cutoff layers 310a and 310b. The supporting layer 320 may include a metal layer or a nonmetal layer. The supporting layer 320 may, for example, include a nickel layer and/or a copper layer. A nonmetal layer may, for example, be a layer of film type and may include a heat hardening material. The nonmetal layer may include an insulating material of a high molecule, for example, a polyimide layer. The protection layer 300 may be formed to have a thickness (342 of FIG. 1B) of about 10 um to about 100 um

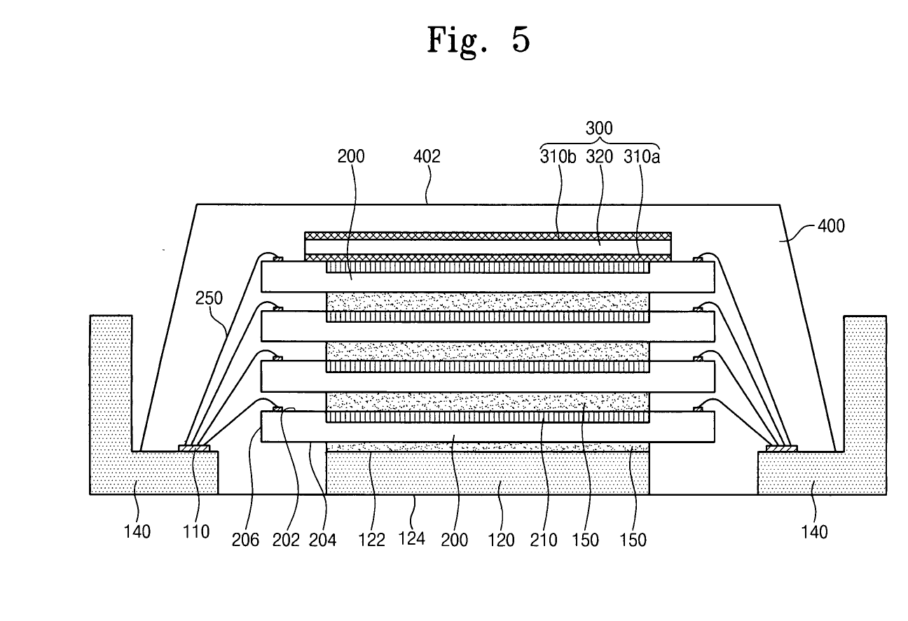

Referring to FIG. 5, a molding material may be injected through a space between the lead patterns 140 and a space between the lead patterns 140 and the die paddle 120 to form a molding portion 400 sealing up the semiconductor chip 200, the die paddle 120, the lead patterns 140, the conductive line 250 and the protection layer 300. The molding portion 400 may be formed of molding resin, for example, an epoxy molding compound (EMC).

The molding portion 400 may have a top surface 402 which may be spaced apart from a top surface of the protection layer 300 and may be parallel to the top surface of the protection layer 300. An exposed surface of the lead patterns 140 may be used to electrically connect the lead patterns 140 to an external device (not shown).

Referring to FIG. 6, a mark pattern 410 may be formed on the top surface 402 of the molding portion 400 using a laser (L) to emit light, for example, infrared light. The laser may emit light in the infrared area. As an example, the light may have a wavelength of about 1160 nm. The mark pattern 410 may be formed to have a predetermined or preset depth. The predetermined or preset depth may be about 45 um to about 65 um.

In accordance with example embodiments, a semiconductor package may include semiconductor chips 200 (which may be laminated) and a molding portion 400. In example embodiments, a distance (340 of FIG. 1B) between the top surface 402 of the molding portion 400 and the first surface 202 of the highest semiconductor chip may be relatively small. Accordingly, a mark pattern 410, that may be formed on the molding portion 400 via a laser, may damage the circuit region 210 of the highest semiconductor chip. However, in accordance with example embodiments, a protection layer 300 may be provided to cover the circuit region 210 of the highest semiconductor chip 200. The protection layer 300 may be configured to reflect and/or absorb an abrupt wave of a light emitted by a laser which may penetrate the molding portion 400 on the circuit region 210 when the mark pattern 410 is formed. Accordingly, defects of the semiconductor chips 200 (e.g., a short circuit in a circuit pattern and an interconnection pattern having a fine line width) may be reduced or minimized, thereby improving a reliability of the semiconductor package 500.

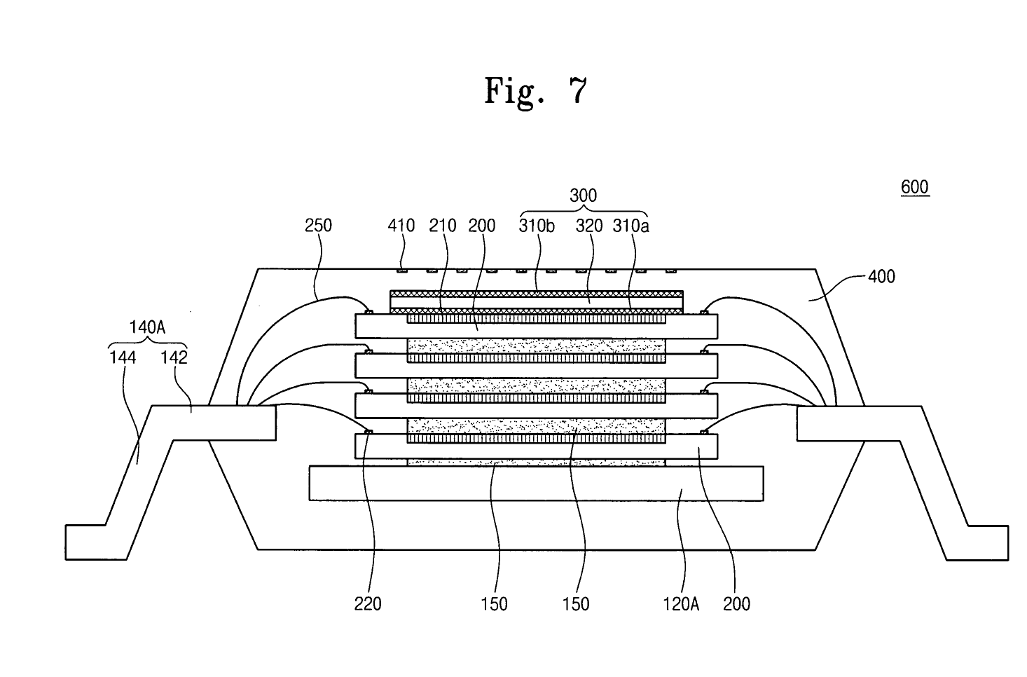

FIG. 7 is a cross sectional view of a semiconductor package according to example embodiments. The semiconductor package illustrated in FIG. 7 may be similar to the semiconductor package illustrated in FIG. 1. Accordingly, the description of common features already discussed before will be omitted or roughly described for brevity.

Referring to FIG. 7, a semiconductor package 600 according to example embodiments may include a die paddle 120A, semiconductor chips 200 on the die paddle 120A, a lead pattern 140A spaced apart from the die paddle 120A and a molding portion 400. The semiconductor package 600 may be a thin small outline package (TSOP).

The lead pattern 140A may be spaced apart from the die paddle 120A to be electrically separated from the die paddle 120A. The lead pattern 140A may include an internal lead pattern 142 and an external lead pattern 144. The internal lead pattern 142 may be disposed in the molding portion 400 and may be spaced apart from the die paddle 120A. The external lead pattern 144 may extend in an outside of the molding portion 400 from the internal lead pattern 142. The external lead pattern 144 may be electrically connected to an external device (not shown).

The semiconductor chips 200 may be stacked on the die paddle 120A by inserting an adhesive layer between the semiconductor chips 200. Each of the semiconductor chips 200 may have a first surface 202 and a second surface 204 facing each other and may include a circuit region 210. Chip pads 220 may be disposed to be adjacent to an edge of the first surface 202 of the semiconductor chip 200. The chip pad 220 may be electrically connected to the internal lead pattern 142 by a conductive line 250.

A protection layer 300 may cover the circuit region 210 of the highest semiconductor chip 200. A mark pattern 410 may be disposed on a top surface 402 of the molding portion 400 on the protection layer 300. Example embodiments may be applied to a semiconductor package including a connection terminal extending outside of a molding portion like a thin film small outline package (TSOP). Example embodiments may also be applied to a package of a ball grid array (BGA) type.

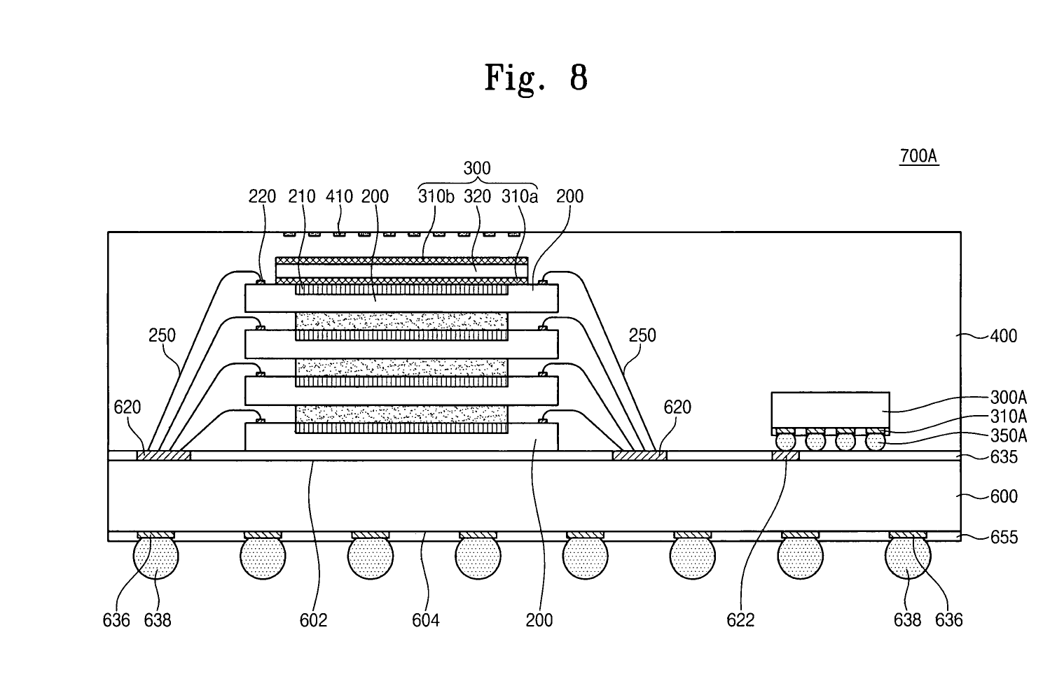

FIG. 8 is a cross sectional view of a semiconductor package according to a second modified embodiment of the present invention. The semiconductor package according to the second application example may be similar to the semiconductor package according to an embodiment of the present invention described before. The description of common features already discussed before will be omitted or roughly described for brevity.

Referring to FIG. 8, a semiconductor package 700A according to example embodiments may include a substrate 600, first semiconductor chips 200 stacked on the substrate 600, and a second semiconductor chip 300A stacked on the substrate 600. The semiconductor package 700A may, for example, be a multi-chip package (MCP).

The substrate 600 may be an interconnection substrate and may include a conductive interconnection (not shown) which may transmit an electrical signal to an inside of the substrate 600. The substrate 600 may include a top surface 602 and a bottom surface 604 facing the top surface 602.

A first substrate pad 620 may be disposed on the top surface 602 of the substrate 600 and may be electrically connected to a conductive interconnection that may be in the substrate 600. A plurality of the first substrate pads 620 may be disposed to be adjacent to edges of the first semiconductor chips 200. The plurality of the fist substrate pads 620 may be spaced apart from one another. An upper insulating layer 635 exposing the first substrate pad 620 may be disposed on the top surface 602 of the substrate 600.

An external connection terminal 638 may be disposed on the bottom surface 604 of the substrate 600. The external connection terminal 638 may be electrically connected to a conductive interconnection of the substrate 600. The external connection terminal 638 may be formed to electrically connect an external device. For example, the external connection terminal 638 may be formed as a solder ball or a solder bump. A connection pad 636 may be interposed between the external connection terminal 638 and the bottom surface 604 of the substrate 600. A lower insulating layer 655 exposing the connection pad 636 may be disposed on the bottom surface 604.

Each of the first semiconductor chips 200 may be stacked on the substrate 600 by the adhesive layer 150. The first semiconductor chips 200 may include a nonvolatile memory, a volatile memory of a random access type and/or other kinds of memory device. The first semiconductor chips 200 may include a flash memory chip, a PRAM chip, a MRAM chip, a SRAM chip, a DRAM chip or combinations thereof.

A plurality of first chip pads 220 corresponding to the plurality of the first substrate pads 620 may be disposed to be adjacent to an edge of each of the first semiconductor chips 200. The plurality of first chip pads 220 may be spaced apart from one another. The first chip pads 220 and the first substrate pads 620 may be electrically connected to each other by the conductive line 250.

The second semiconductor chip 300A may be disposed on the top surface 602 of the substrate 600. The second semiconductor chip 300A may be spaced apart from the first semiconductor chips 200. The second semiconductor chip 300A may be a chip performing a function different from the first semiconductor chips 200. For example, the second semiconductor chip 300A may be a controller chip or a logic chip. The second semiconductor chip 300A may include at least one of a micro processor, a digital signal processor, and/or a microcontroller.

A second substrate pad 622 may be spaced apart from the first substrate pad 620. A plurality of the second substrate pads 622 may have the same thickness and level as the first substrate pad 620 and may be disposed on the top surface 602 of the substrate 600. The second substrate pad 622 may be electrically connected to a conductive interconnection that may be formed in the substrate 600. The upper insulating layer 635 may expose the second substrate pad 622.

A second chip pad 310A may be disposed on a bottom surface of the second semiconductor chip 300A. The second chip pad 310A may be electrically connected to a circuit pattern (not shown) formed on the second semiconductor chip 300A. A plurality of the second chip pads 310A may correspond to a plurality of the second substrate pads 622 that may be disposed to be spaced apart from one another. A connection terminal 350A (e.g., a solder bump or a solder ball) may be interposed between the second chip pad 310A and the second substrate pad 622. The second chip pad 310A and the second substrate pad 622 may be electrically connected to each other through the connection terminal 350A and the first semiconductor chips 200 and the second semiconductor chip 300A may be electrically connected to each other through an interconnection circuit of the substrate 600. A molding portion 400 may seal the first semiconductor chips 200 and the second semiconductor chip 300A.

The protection layer 300 may cover a circuit region 210 of the highest first semiconductor chip among the first semiconductor chips 200. A mark pattern 410 may be disposed on a top surface of the molding portion 400 on the protection layer 300. According to above disclosure, example embodiments may be applied to a multi-chip package (MCP).

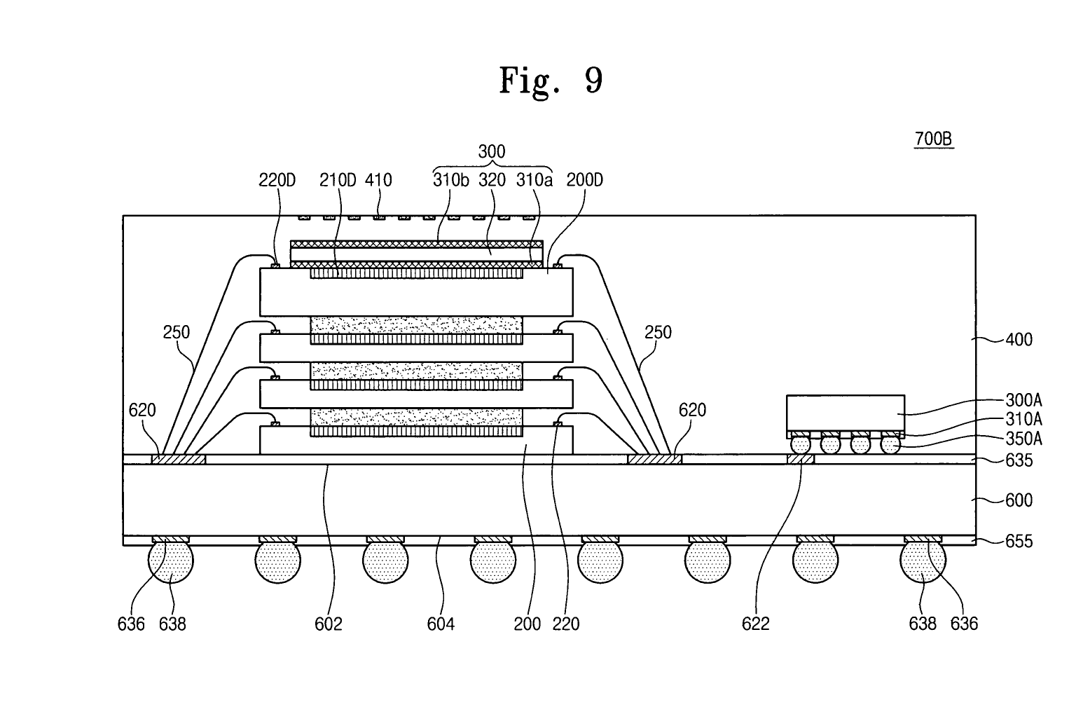

FIG. 9 is a cross sectional view of a semiconductor package according to example embodiments. The example semiconductor package illustrated in FIG. 9 may be similar to previously described semiconductor packages according to example embodiments. The description of common features already discussed before will be omitted or roughly described for brevity.

Referring to FIG. 9, a semiconductor package 700B, according to example embodiments, may include first semiconductor chips 200 and a central processing unit (CPU) chip 200D on the first semiconductor chips 200. As shown in FIG. 9, the semiconductor chips 200 may be laminated. The semiconductor package 700B may be a system in package (SIP).

The CPU chip 200D may include a circuit region 210D in which a circuit pattern may be formed and a chip pad 220D. The chip pad 220D may be electrically connected to the circuit pattern. The chip pad 220D may electrically contact the first substrate pad 620 through a conductive line 250 thereby electrically connecting the first semiconductor chips 200 and the CPU chip 200D to each other.

A protection layer 300 may cover the circuit region 210D of the CPU chip 200D. A mark pattern 410 may be disposed on a top surface of a molding portion 400 on the protection layer 300. According to the above disclosure, example embodiments may be applied to a multi-chip package (MCP).

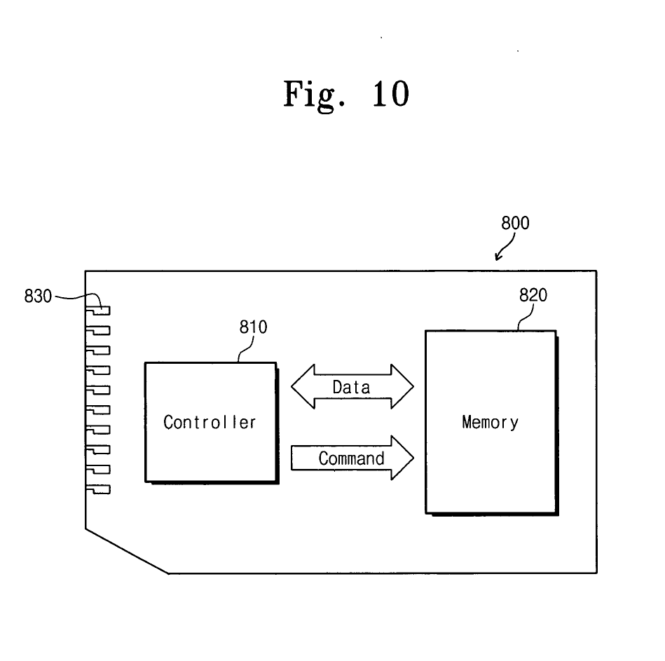

FIG. 10 is a cross sectional view of a memory card system including a semiconductor package according to example embodiments.

Referring to FIG. 10, a memory card system 800 may include a semiconductor package according to example embodiments. The memory card system 800 may include a controller 810, a memory 820, and an interface 830. The memory 820 may be used to store a command executed by the controller 810 and/or user data. The controller 810 and the memory 820 may be constructed to transfer the command and/or the data and to receive the command and/or the data. The interface 830 may perform a function of inputting data from the outside and outputting data to the outside.

The memory card system 800 may be a multimedia card (MMC), a secure digital card (SD) or a portable data storage device.

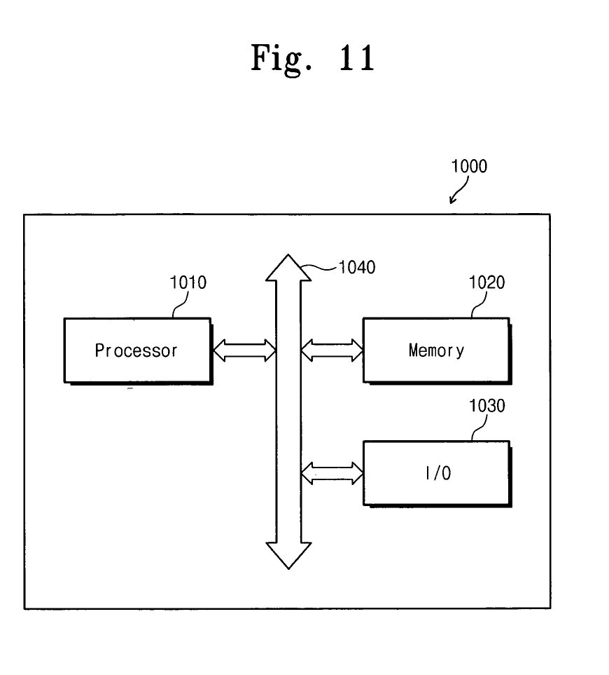

FIG. 11 is a block diagram of an electronic device including a semiconductor package according to example embodiments.

Referring to FIG. 11, an electronic device 1000 may include a semiconductor package according to example embodiments. The electronic device 1000 may include a processor 1010, a memory 1020, and an input/output device 1030. The processor 1010, the memory 1020 and the input/output device 1030 may be connected to one another through a bus 1040. The memory 1020 may receive a control signal, for example, RAS*, WE* and CAS*, from the processor 1010. The memory 1020 may be used to store data accessed through the bus 1040. It will be apparent by one of ordinary skill in the art that additional circuits and control signals may be provided to embody or modify example embodiments.

The electronic device 1000 may be used in a computer system, a wireless communication device, for example, PDA, a laptop computer, a portable computer, a web tablet, a wireless telephone, a cell phone, a digital music player, a MP3 player, a navigation, a solid state disk (SSD), a household appliance and/or a device which can transmit data or receive data in a wireless environment.

The foregoing is illustrative of the present invention and is not to be construed as limiting thereof. Although example embodiments of the present invention have been described, those skilled in the art will readily appreciate that many modifications are possible in example embodiments without materially departing from the novel teachings and advantages of the present invention. Accordingly, all such modifications are intended to be included within the scope of the present invention as defined in the claims. Therefore, it is to be understood that the foregoing is illustrative of the present invention and is not to be construed as limited to example embodiments disclosed, and that modifications to example embodiments are intended to be included within the scope of the appended claims. The present invention is defined by the following claims, with equivalents of the claims to be included therein

1.-17. (canceled)

18. A semiconductor package comprising:
a protection layer covering a circuit region of at least one semiconductor chip;
a molding portion sealing the protection layer and the at least one semiconductor chip, the molding portion having an exposed top surface on the circuit region; and
a mark pattern at the top surface of the molding portion.

19. The semiconductor package of claim 18, wherein the circuit region includes a conductive circuit pattern at an upper surface of the at least one semiconductor chip and an interconnection pattern electrically connected to the circuit pattern, and the protection layer is configured to protect the circuit pattern and interconnection pattern.

20. The semiconductor package of claim 18, wherein the protection layer includes a first cutoff layer covering the circuit region.

21. The semiconductor package of claim 20, wherein the first cutoff layer is configured to at least one of reflect and absorb light emitted from a laser.

22. The semiconductor package of claim 18, the protection layer has a thickness of about 10 to about 100 um.

23. The semiconductor package of claim 18, wherein the protection layer further includes
a supporting layer on the first cutoff layer, and
a second cutoff layer on the supporting layer, wherein the first and second cutoff layers are configured to at least one of reflect and absorb light emitted from a laser, and the supporting layer is configured to support the first and second cutoff layers.

24. The semiconductor package of claim 23, the first cutoff layer and second cutoff layer are layers of film type having an adhesive property.

25. The semiconductor package of claim 23, the first cutoff layer and second cutoff layer are at least one of a bisphenol resin, a novolac resin.

26. The semiconductor package of claim 23, the supporting layer absorbs an external shock and supports the first and second cutoff layers.

27. The semiconductor package of claim 23, the supporting layer is at least one of a nickel layer, a copper layer and a heat hardening material.

28. The semiconductor package of claim 23, wherein the protection layer covers a portion of the circuit region under the mark pattern.

29. The semiconductor package of claim 18, further comprising:
a die paddle with a top surface and a bottom surface; and
lead patterns spaced apart from the die paddle, the lead patterns electrically connected to the circuit region, wherein the at least one semiconductor chip is on the top surface of the die paddle.

30. The semiconductor package of claim 29, wherein the protection layer covers the circuit region of the at least one semiconductor chip adjacent to the mark pattern.

31. The semiconductor package of claim 29, wherein the molding portion partially seals the die paddle and the lead patterns and exposes the bottom surface of the die paddle and a portion of the lead patterns.

32. The semiconductor package of claim 31, wherein the lead patterns include internal lead patterns and external lead patterns, the external lead patterns being exposed by the molding portion and the internal lead patterns being electrically connected the circuit region.

33. The semiconductor package of claim 18, further comprising:
a substrate with a top surface and a bottom surface, the substrate including at least one substrate pad; and
a second semiconductor chip electrically connected to the substrate, wherein the at least one semiconductor chip is on the top surface of the substrate and the at least one semiconductor chip is electrically connected to the at least one substrate pad.

34. The semiconductor package of claim 33, wherein the at least one semiconductor chip includes at least one central processing unit.

35. The semiconductor package of claim 18, wherein the mark pattern includes product information.

36. The semiconductor package of claim 35, wherein the product information is one of a lot number and a product name.
